(19) United States
(12) Patent Application Publication
(10) Pub. No.: US 2025/0220843 A1
(43) Pub. Date: Jul. 3, 2025

(54) TELECOMMUNICATIONS RACK AND ADJUSTABLE CHASSIS

(71) Applicant: AFL Telecommunications LLC, Duncan, SC (US)

(72) Inventors: Dhiren Ashvin Damani, Milton Keynes (GB); Asher Leong Raven, Milton Keynes (GB); Chi Yu Choi, Milton Keynes (GB)

(21) Appl. No.: 18/985,808

(22) Filed: Dec. 18, 2024

Related U.S. Application Data
(60) Provisional application No. 63/614,963, filed on Dec. 27, 2023.

(51) Int. Cl. H05K 7/14; H05K 7/18

(52) U.S. Cl. CPC H05K 7/1489; H05K 7/186

(57) ABSTRACT

A system for telecommunications cable equipment mounting, the system including a rack including a frame, a bracket, a chassis, and a latch. The frame includes a frame opening. The bracket is attachable to the frame at the frame opening. The chassis forms a body including sidewalls separated from one another along a width direction and extending along a transverse direction. The latch is configured to selectively lock and release the chassis relative to the bracket. The bracket includes a bracket wall extending co-directional to the sidewalls. The wall forms a guide slot extending co-directional to the sidewalls, the wall forming an opening. The latch includes a lock tab configured to extend into the opening at the bracket. The latch includes a user interface tab configured to articulate the lock tab in and out of the opening.

### PRIORITY STATEMENT

The present disclosure claims the benefit of priority to U.S. provisional patent application 63/614,963, filed Dec. 27, 2023, the disclosure of which is incorporated herein in its entirety.

### FIELD

The present disclosure relates generally to structures for telecommunications equipment, and more particularly, to telecommunications racks and chassis therefor.

### BACKGROUND

Speed of deployment of optical networks is critical for organizations to begin earning revenue from their capital expenditure. As such some methods of deploying optical networks, specifically splicing, requires skilled labor and can be time consuming, approximately 5 minutes per 12 fiber ribbon splice.

A telecommunications system may generally include an optical chassis mounted to a data rack at a data center. Chassis generally require adjustment relative to a mounting profile of the rack, such as prior to installation of the chassis to the rack. Installation and adjustment generally requires insertion, removal, and articulation of fasteners, such as screws, bolts, or threaded shanks, which may require hand tools. The use of hand tools may lead to health and safety issues for a technician, or increase the time of deployment and servicing, or risk adverse outcomes associated with insufficient threading and fastening.

A data center may include a plurality of different racks having different configurations and requirements. Such differences can result in multiple variants of chassis, which may include different fasteners. Such differences may require accessibility to the different fasteners, require disassembly and reassembly of the chassis to meet different configurations, or require different pre-configured assemblies to be stocked.

Accordingly, improved telecommunications racks and chassis therefor that facilitate improved optical network deployment and/or address one or more above identified issues are desired in the art and would be advantageous.

### BRIEF DESCRIPTION

Aspects and advantages of the invention will be set forth in part in the following description, may be apparent from the description, or may be learned through practice of the invention.

An aspect of the present disclosure is directed to a system for telecommunications cable equipment mounting. The system includes a rack including a frame, a bracket, a chassis, and a latch. The frame includes a frame opening. The bracket is attachable to the frame at the frame opening. The chassis forms a body including sidewalls separated from one another along a width direction and extending along a transverse direction. The latch is configured to selectively lock and release the chassis relative to the bracket. The bracket includes a bracket wall extending co-directional to the sidewalls. The wall forms a guide slot extending co-directional to the sidewalls, the wall forming an opening. The latch includes a lock tab configured to extend into the opening at the bracket. The latch includes a user interface tab configured to articulate the lock tab in and out of the opening.

These and other features, aspects and advantages of the present invention will become better understood with reference to the following description and appended claims. The accompanying drawings, which are incorporated in and constitute a part of this specification, illustrate embodiments of the invention and, together with the description, serve to explain the principles of the invention.

### BRIEF DESCRIPTION OF THE DRAWINGS

A full and enabling disclosure of the present invention, including the best mode thereof, directed to one of ordinary skill in the art, is set forth in the specification, which makes reference to the appended figures.

FIG. 1 depicts a perspective view of an exemplary embodiment of a system for telecommunications cable equipment mounting in accordance with aspects of the present disclosure;

FIG. 2 depicts a perspective view of an exemplary embodiment of movement of a chassis at an adjustable bracket in accordance with aspects of the present disclosure;

FIG. 3 depicts a perspective view of an exemplary embodiment of the chassis at the bracket in accordance with aspects of the present disclosure;

FIG. 4 depicts a perspective view of an exemplary embodiment of the chassis at the bracket in accordance with aspects of the present disclosure;

FIG. 5 depicts a detailed perspective view of an exemplary embodiment of the chassis at the bracket in accordance with aspects of the present disclosure;

FIG. 6 depicts a cutaway detailed perspective view of an exemplary embodiment of the chassis at the bracket in accordance with aspects of the present disclosure;

FIG. 7 depicts a detailed perspective view of an exemplary embodiment of the chassis in accordance with aspects of the present disclosure;

FIG. 8 depicts a plan view of an exemplary embodiment of the bracket at the chassis in accordance with aspects of the present disclosure;

FIG. 9 depicts a detailed perspective view of an exemplary embodiment of the chassis at the bracket in accordance with aspects of the present disclosure;

FIG. 10 depicts a perspective view of an exemplary embodiment of the chassis at the bracket in accordance with aspects of the present disclosure;

FIG. 11 depicts a perspective view of an exemplary embodiment of the chassis at the bracket in accordance with aspects of the present disclosure.

### DETAILED DESCRIPTION

Reference now will be made in detail to embodiments of the invention, one or more examples of which are illustrated in the drawings. Each example is provided by way of explanation of the invention, not limitation of the invention. In fact, it will be apparent to those skilled in the art that various modifications and variations can be made in the present invention without departing from the scope or spirit of the invention. For instance, features illustrated or described as part of one embodiment can be used with another embodiment to yield a still further embodiment. Thus, it is intended that the present invention covers such modifications and variations as come within the scope of the appended claims and their equivalents.

As used herein, the terms “first,” “second,” and “third” may be used interchangeably to distinguish one component from another and are not intended to signify location or importance of the individual components. The terms “includes” and “including” are intended to be inclusive in a manner similar to the term “comprising.” Similarly, the term “or” is generally intended to be inclusive (i.e., “A or B” is intended to mean “A or B or both”). In addition, here and throughout the specification and claims, range limitations may be combined and/or interchanged. Such ranges are identified and include all the sub-ranges contained therein unless context or language indicates otherwise. For example, all ranges disclosed herein are inclusive of the endpoints, and the endpoints are independently combinable with each other. The singular forms “a,” “an,” and “the” include plural references unless the context clearly dictates otherwise.

Approximating language, as used herein throughout the specification and claims, may be applied to modify any quantitative representation that could permissibly vary without resulting in a change in the basic function to which it is related. Accordingly, a value modified by a term or terms, such as “generally,” “about,” “approximately,” and “substantially,” are not to be limited to the precise value specified. In at least some instances, the approximating language may correspond to the precision of an instrument for measuring the value, or the precision of the methods or machines for constructing or manufacturing the components and/or systems. For example, the approximating language may refer to being within a 10 percent margin, i.e., including values within ten percent greater or less than the stated value. In this regard, for example, when used in the context of an angle or direction, such terms include within ten degrees greater or less than the stated angle or direction, e.g., “generally vertical” includes forming an angle of up to ten degrees in any direction, e.g., clockwise or counterclockwise, with the vertical direction V.

The word “exemplary” is used herein to mean “serving as an example, instance, or illustration.” In addition, references to “an embodiment” or “one embodiment” does not necessarily refer to the same embodiment, although it may. Any implementation described herein as “exemplary” or “an embodiment” is not necessarily to be construed as preferred or advantageous over other implementations. Moreover, each example is provided by way of explanation of the invention, not limitation of the invention. In fact, it will be apparent to those skilled in the art that various modifications and variations can be made in the present invention without departing from the scope of the invention. For instance, features illustrated or described as part of one embodiment can be used with another embodiment to yield a still further embodiment. Thus, it is intended that the present invention covers such modifications and variations as come within the scope of the appended claims and their equivalents.

Dimensions provided herein may include approximations of +/−2% of any discrete quantity, or approximations of +2% of a maximum value over a given range or −2% of the maximum value under the given range, unless otherwise provided herein.

As used herein, the term “rack unit” (RU) is understood by those skilled in the art as a unit of measure of approximately 1.75 inches (in) or approximately 44.45 millimeters (mm), or up to 0.03125 in or 0.794 mm less when applied to telecommunications equipment attached to a mount structure.

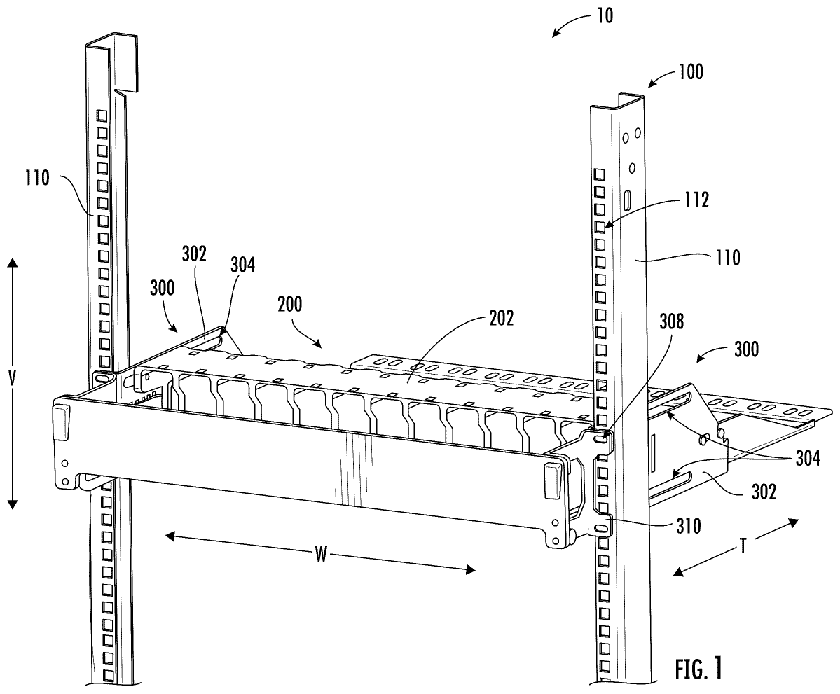

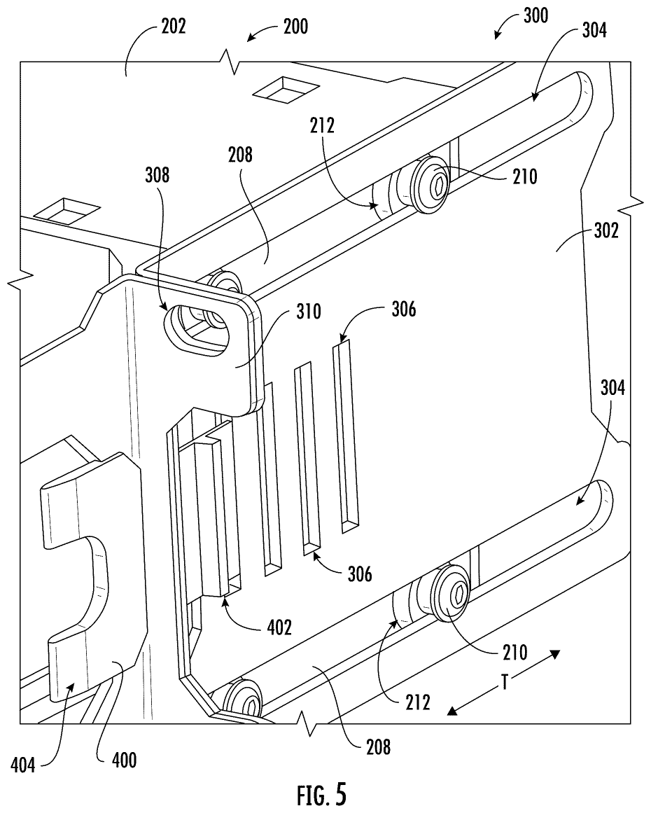

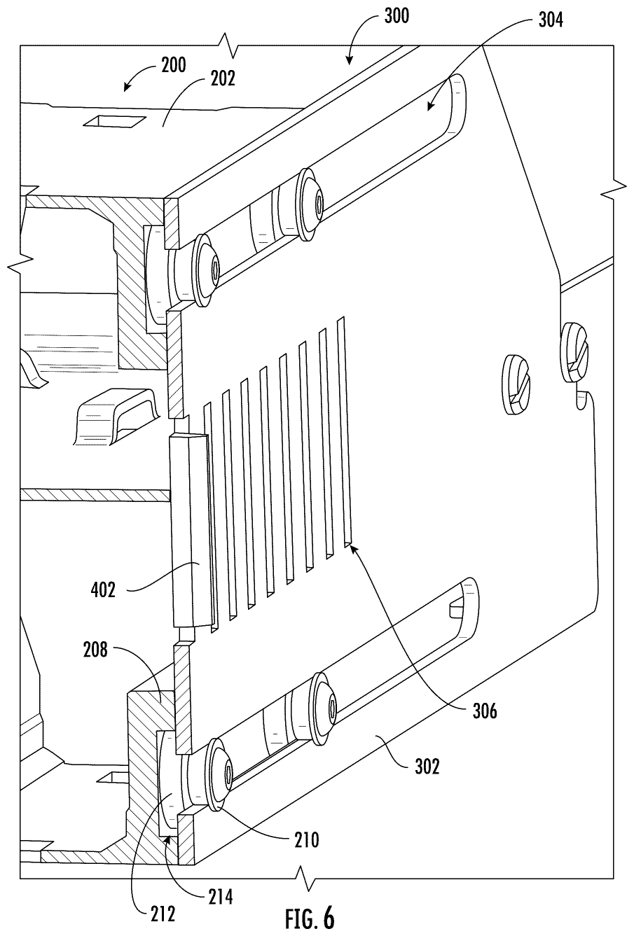

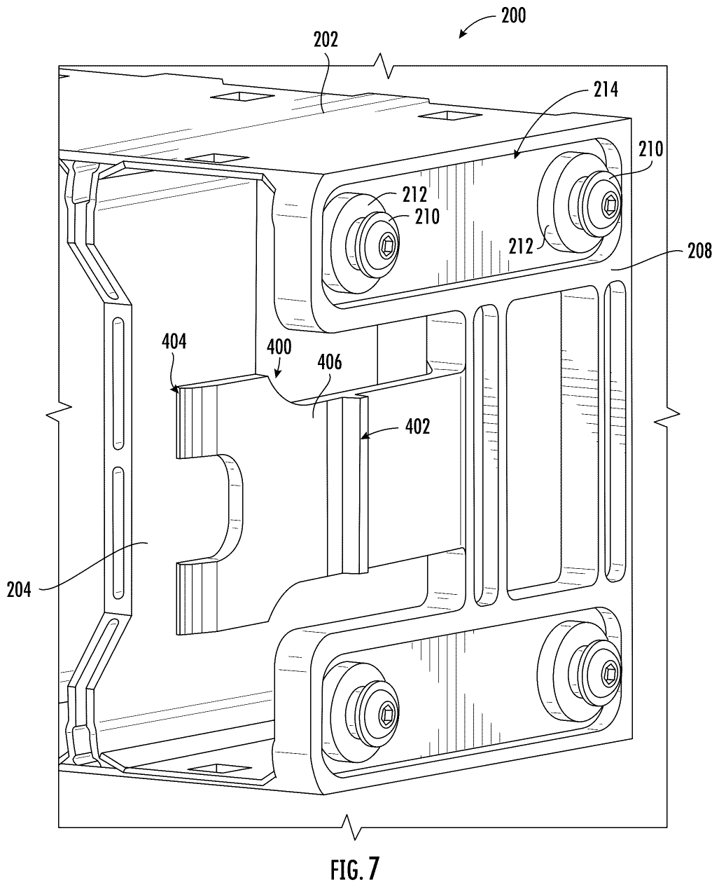

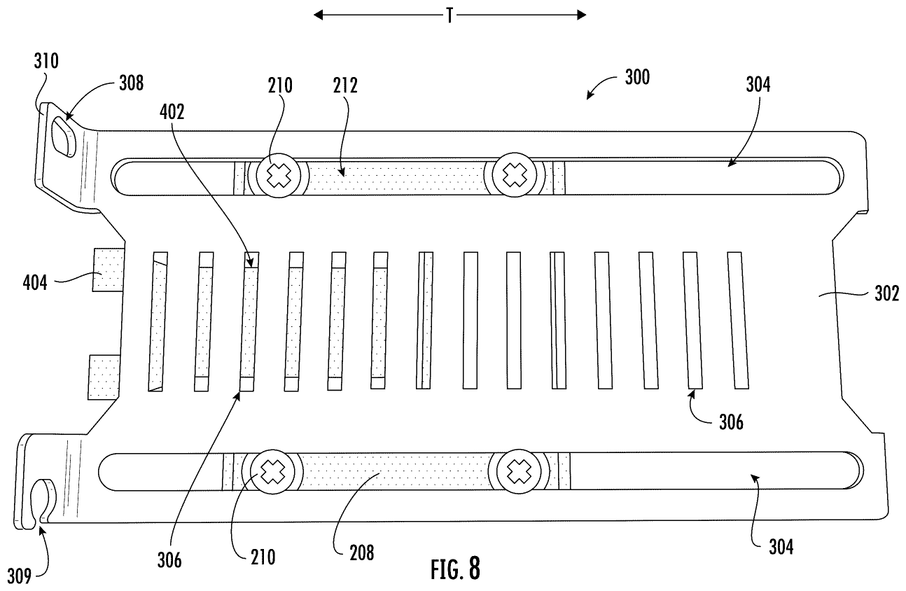

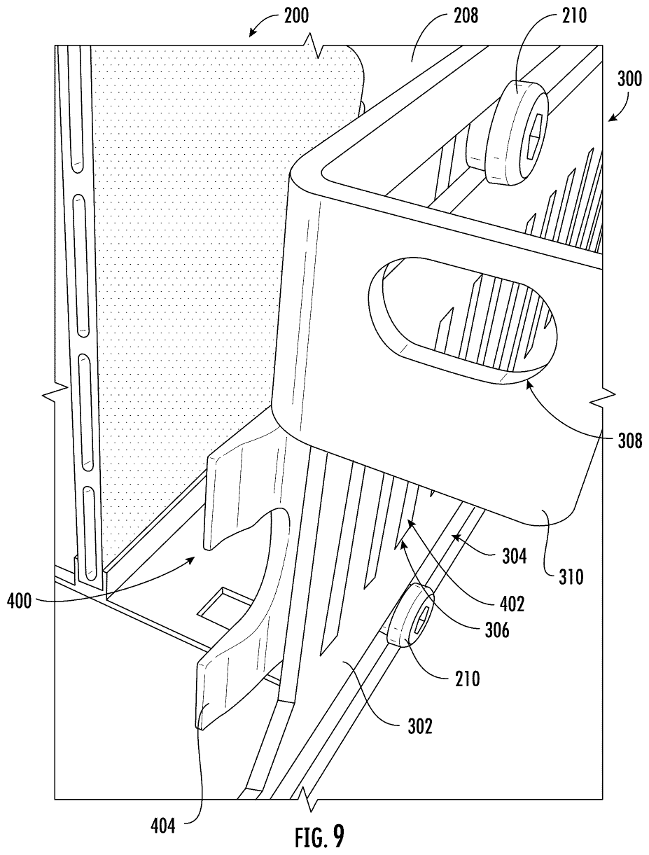

Referring now to the drawings, FIGS. 1-11 depict embodiments of a telecommunications system 10, a rack 100, and a chassis 200 and an adjustable bracket 300 that address one or more of the aforementioned issues. Embodiments of the chassis 200 form a housing for modules, cassettes, or other telecommunications equipment, such as for fiber optic connectivity. The chassis 200 includes one or more outer walls 202 forming a protective housing for various telecommunications equipment, such as, but not limited to, internal and external optical fibers, optical fiber connectors, modules, cassettes, patchcords, fiber management, housing access doors, or combinations thereof. The outer walls 202 may include sidewalls 208 separated from one another along a width direction W. Sidewalls 208 may extend substantially along a transverse direction T and substantially along a vertical direction V. Internal walls 204 may form partitions between the sidewalls 208 along the width direction W, such as forming one or more volume(s) 206 for housing, organizing, or separating telecommunications equipment.

The chassis 200 may generally form a body extending along the width direction W, the transverse direction T, and the vertical direction V. For instance, the chassis 200 may extend along the vertical direction V for one or more rack units, or portions thereof. The chassis 200 may extend along the width direction W corresponding to one or more dimensions, such as, but not limited to, approximately 19 inches, or 21 inches, or 23 inches, or non-standard dimensions greater or less than the aforementioned dimensions.

In some embodiments, the chassis 200 is formed as a unitary, monolithic component. The chassis 200 may be molded as a single body of a plastic material. In various embodiments, the chassis 200 includes a polybutylene terephthalate (PBT) material. In still some embodiments, the chassis 200 forming a unitary, monolithic body includes a PBT plus 30% glass fill, such as may mitigate a risk of deflection under load.

The bracket 300 includes a wall 302 configured to extend substantially co-directional to the sidewall 208, such as substantially along the transverse direction T. The bracket 300 is selectively attachable alongside the sidewall 208. The bracket 300 includes guide slot 304 extending through the wall 302. The guide slot 304 extends into the wall 302 substantially co-directional to an extension of the sidewall 208, such as substantially along transverse direction T. In some embodiments, the bracket 300 may include a plurality of guide slots 304 extending through the wall 302. For instance, the wall 302 may form the guide slot 304 proximate to an upper edge of the chassis 200 (e.g., at a junction of the sidewall 208 and the outer wall 202 forming a top wall). In another instance, the wall 302 may form the guide slot 304 proximate to a lower edge of the chassis 200 (e.g., at a junction of the sidewall 208 and the outer wall 202 forming a base wall).

The bracket 300 forms a lock opening 306 extending into the wall 302. The opening 306 is configured to receive a lock tab 402 at a latch 400. The latch 400 is configured to selectively lock and release a position of the chassis 200 relative to the bracket 300 relative to an extension of the sidewall 208, such as substantially along the transverse direction T. The latch 400 includes a user interface tab 404 at which a user may pull or press to articulate the lock tab 402 in and out of the opening 306.

The latch 400 may form a wall or platform 406 extending substantially co-directional to the sidewall 208, such as substantially along transverse direction T. The lock tab 402 may extend from the platform 406 at a first end to the user interface tab 404 at a second end distal to the first end. In still various embodiments, the lock tab 402 may be positioned along the platform 406 between the first end and the second end, such as along a central portion of the platform 406.

In various embodiments, the latch 400 is positioned between the sidewall 208 and the wall 302 of the bracket 300. In some embodiments, the latch 400 is attached to or integral to the chassis 200. The latch 400 may be attached by fasteners or a joining process, such as, but not limited to, welding, brazing, etc., or integrally formed to the outer wall 202, such as the sidewall 208.

In some embodiments, the opening 306 may extend substantially orthogonal to the guide slot 304, such as substantially along the vertical direction V. The lock tab 402 may extend substantially correspondingly to the opening 306, such as along the vertical direction V. However, it should be appreciated that the opening 306 and lock tab 402 may form any appropriate geometry, such as, but not limited to, round or polygonal openings, elliptical openings, or other geometries.

In various embodiments, a plurality of openings 306 are formed at the wall 302 in adjacent arrangement substantially co-directional to the extension of the sidewall 208, such as substantially along the transverse direction T. The adjacent arrangement of openings 306 may facilitate positioning and locking of the chassis 200 in various discrete positions along the transverse direction T. For instance, openings 306 may facilitate extending the chassis 200 out of the rack 100 along transverse direction T.

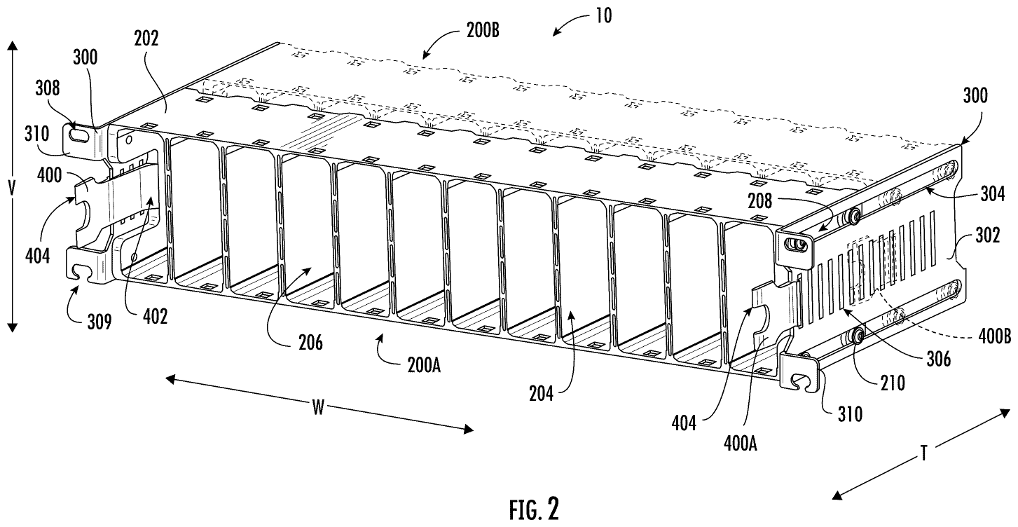

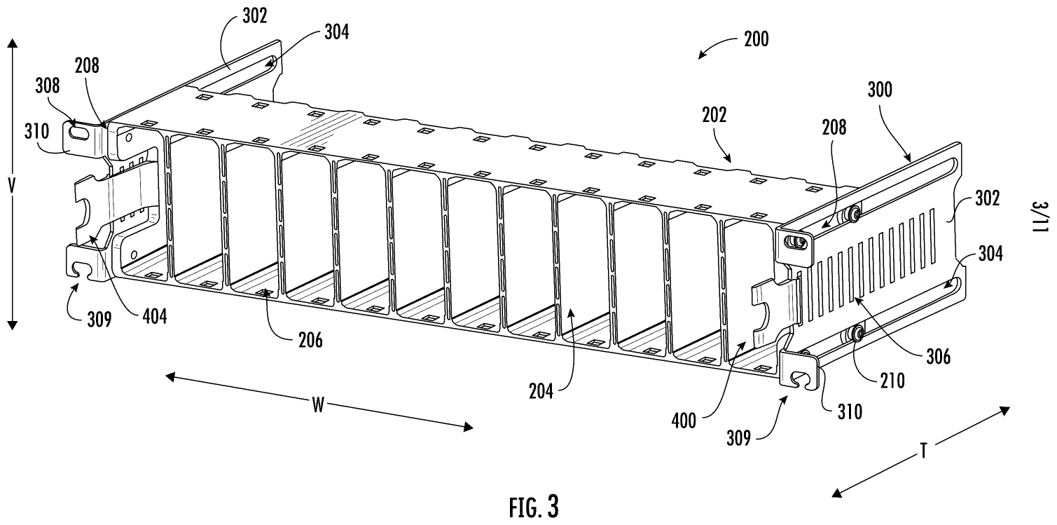

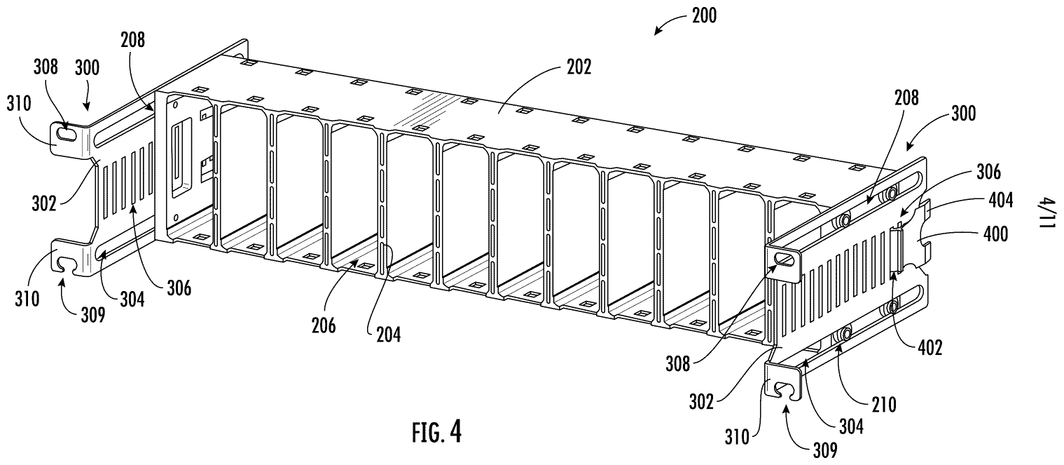

For instance, FIG. 2 depicts an exemplary operation of the system 10 in which the chassis extends between a first position, depicted at chassis 200A, and a second position, depicted at chassis 200B displaced from chassis 200A along the transverse direction T. FIG. 2 further depicts the latch translating with the chassis, such as depicted between a first position of the latch 400A and a second position of the latch depicted at latch 400B. FIG. 3 further depicts an embodiment of the chassis 200 (e.g., in the second position) displaced in the guide slot 304 along the transverse direction T relative to the depiction of the embodiment of the chassis 200 in FIG. 4 (e.g., in the first position).

In various embodiments, a positioning member 210 may extend from the sidewall 208, such as orthogonal to an extension of the sidewall 208. The positioning member 210 is configured to extend through the guide slot 304 at the bracket 300, such as along the width direction W from the sidewall 208 into the guide slot 304. For instance, the positioning member 210 may provide a contact surface at which the chassis 200 rides on the bracket 300 at the guide slot 304. The positioning member 210 may include a wall configured to extend onto the wall 302, such as to facilitate retaining the positioning member 210 within the guide slot 304.

In some embodiments, a post 212 extends from the sidewall 208 substantially co-directional to the extension of the positioning member 210 from the sidewall 208. The positioning member 210 may extend from the post 212. The post 212 may form a surface alongside which the wall 302 of the bracket 300 may rub, slide, or glide. For instance, an inside surface of the wall 302 adjacent to the sidewall 208 may rub, slide, or glide against the post 212. The post 212 may form a bushing from which the positioning member 210 extends, or against which the wall 302 may contact, or both.

In still some embodiments, the sidewall 208 may form a recess 214 extending into the sidewall 208. The post 212, the positioning member 210, or both, may be positioned within the recess 214. The recess 214 may form a groove extending substantially co-directional to the extension of the sidewall 208, such as substantially along the transverse direction T. The post 212 may be moveable within the recess 214. The positioning member 210 may be moveable with the post 212. The post 212 may facilitate translation of the chassis 200 along the transverse direction T relative to the rack 100.

In various embodiments, the bracket 300 may include a mount opening 308 configured to attach to the rack 100. Referring to FIG. 1, the rack 100 may generally include rails or a frame 110 forming an opening 112. The mount opening 308 may correspond to the opening 112 at the rack 100, such as to allow a fastener to extend through the openings 112, 308 to secure the bracket 300 to the rack 100. The fastener may include, but is not limited to, a mechanical fastener, such as a threaded shank, bolt and nut, screw, tie rod, rod, or member. The openings 112 may be distributed along the vertical direction V to allow for various positions of the bracket 300 along the vertical direction V.

The mount opening 308 may extend through the wall 302. The bracket 300 may include a mount tab 310 extending orthogonal to the extension of the wall 302, such as along the width direction W. The mount opening 308 may extend through the mount tab 310, such as to facilitate forward access (e.g., along transverse direction T) to a mount interface of the bracket 300 and the rack 100.

In some embodiments, one or more mount openings 308 may form a hole extending into the wall 302 or mount tab 310. In still some embodiments, one or more mount openings 308 may form a slot or open-ended opening, such as depicted at mount opening 309. For instance, the mount opening 309 may form an open-ended opening extending along the vertical direction V. The mount opening 309 may extend downward along the vertical direction V, such as to allow the user to slide the bracket onto a fastener, rod, or member at the rack 100 to position the bracket 300 along the vertical direction V.

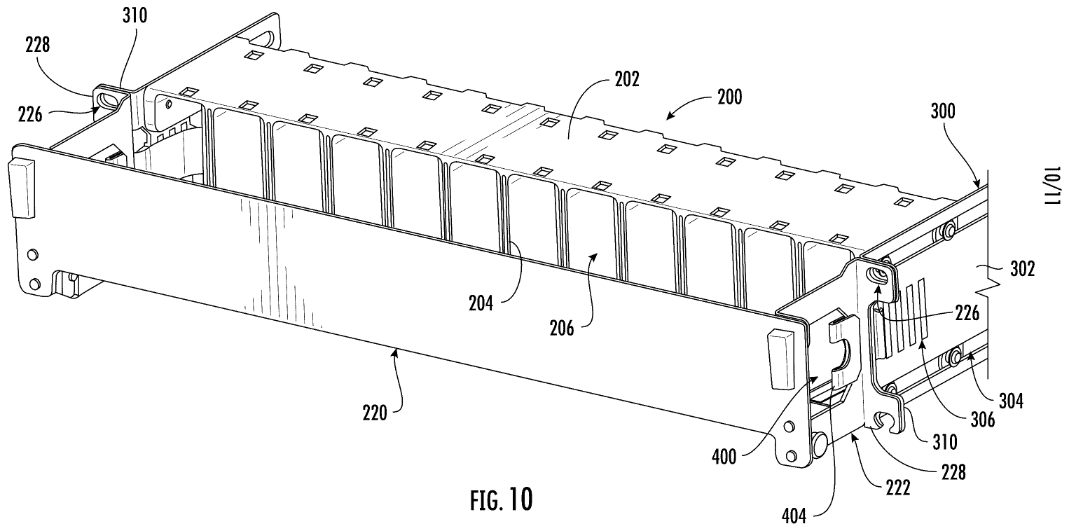

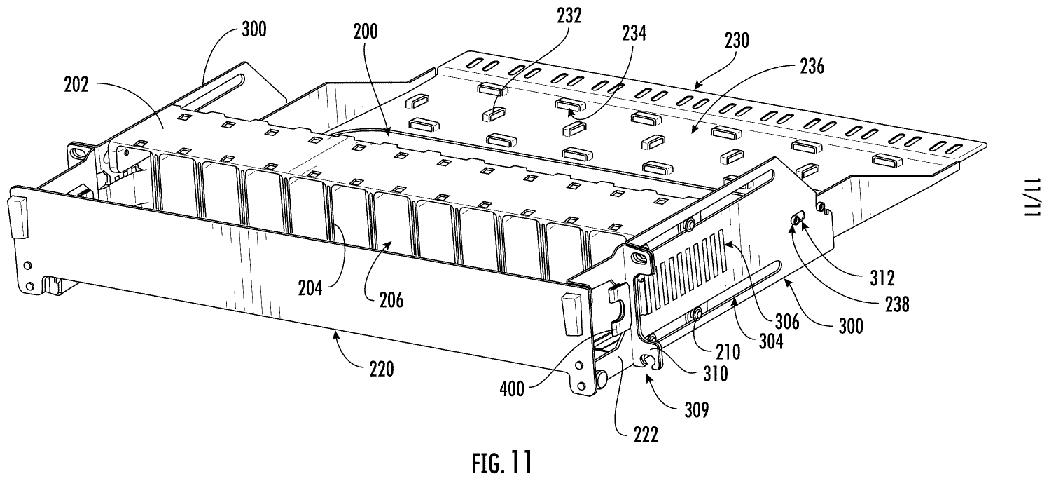

Referring now to FIGS. 10-11, a door 220 may be positioned in front of the chassis 200, such as in front along the transverse direction T. The door 220 may extend along the width direction W, such as to cover or obscure the volume(s) 206 at the chassis 200, such as to secure telecommunications equipment at the volume(s) 206. A mount bracket 222 may extend from the bracket 300. The door 220 may be attached to the mount bracket 222. For instance, the mount bracket 222 may include openings 226 and tabs 228 corresponding to the mount tab 310 and one or more openings 308, 309. A fastener may extend through one or more openings 308, 309 to affix the bracket 222 to the bracket 300.

Referring now to FIG. 11, a tray 230 may extend along the transverse direction T from the chassis 200. The tray 230 may form a rear management tray at which optical fiber cables or other telecommunications equipment may be positioned. For instance, lances or bridges 232 at a base surface 236 of the tray 230 may form openings 234 configured to receive attachment mechanisms, such as cable attachment bases, tubes, or straps. In some embodiments, the wall 302 may include a mount opening 312 configured to receive a fastener 238 to allow for the tray 230 to selectively affix to the bracket 300.

Embodiments of the system 10, rack 100, chassis 200, and bracket 300 provided herein may allow for a position of the chassis 200 to be adjusted after mounting the chassis 200 to the rack 100, without requiring threaded fasteners, hand tools, or other tooling. Overall weight may be decreased, volume may be increased, component quantity may be decreased, or combinations thereof, at the chassis 200 by removing interfaces that may require threaded fasteners. Implementation, deployment, and servicing time may be reduced by obviating a need for tools to adjust a translating position or vertical position of the chassis 200 at the rack 100.

Various embodiments provided herein may include a plurality of brackets 300 positioned at the rack 100, such as in adjacent arrangement along the vertical direction V.

Various embodiments may include the bracket 300 formed of any appropriate material, such as, but not limited to, a metal material. The chassis 200 may be formed substantially of a plastic material. The metal bracket and the plastic chassis may facilitate reduced overall weight, increased volume, or increased strength (e.g., to retain additional telecommunications equipment).

Still various embodiments of the bracket 300 may facilitate front or rear positioning or orientation at the chassis 200 using the same bracket configuration, such as to facilitate additional mounting options of the chassis 200 to the rack 100.

Further aspects of the present disclosure are provided in one or more of the following clauses:

1. A system 10 for telecommunications equipment mounting, the system 10 including a rack 100 including a frame 110, the frame 110 including a frame opening 112; a bracket 300 attachable to the frame 110 at the frame opening 112; and a chassis 200 forming a body including sidewalls 208 separated from one another along a width direction and extending along a transverse direction; and a latch 400 configured to selectively lock and release the chassis 200 relative to the bracket 300, wherein the bracket 300 includes a wall 302 extending co-directional to the sidewalls 208, the wall 302 forming a guide slot 304 extending co-directional to the sidewalls 208, the wall 302 forming an opening 306, wherein the latch 400 includes a lock tab 402 configured to extend into the opening 306 at the bracket 300, the latch 400 including a user interface tab 404 configured to articulate the lock tab 402 in and out of the opening 306.

2. The system 10 of any one or more clauses herein, wherein the bracket 300 includes a plurality of openings 306 positioned in adjacent arrangement co-directional to an extension of the sidewalls 208.

3. The system 10 of any one or more clauses herein, wherein the latch 400 is attached to the sidewalls 208.

4. The system 10 of any one or more clauses herein, the sidewalls 208 comprising a positioning member 210 extending from the sidewall 208, wherein the positioning member 210 is configured to extend into the guide slot 304 at the bracket 300.

5. The system 10 of any one or more clauses herein, the sidewalls 208 including a post 212 extending from the sidewall 208, wherein a positioning member 210 extends from the post 212 into the guide slot 304 at the bracket 300.

6. The system 10 of any one or more clauses herein, the sidewalls 208 forming a recess 214, wherein a post 212 extends from the recess 214, and wherein a positioning member 210 extends from the post 212 into the guide slot 304 at the bracket 300.

7. The system 10 of any one or more clauses herein, the bracket 300 including a mount opening 308 configured to receive a fastener extending through the mount opening 308 and the frame opening 112 at the rack 100.

8. The system 10 of any one or more clauses herein, the bracket 300 including a mount tab 310 extending orthogonal to an extension of the bracket 300 wall, wherein a mount opening 308 extends through the mount tab 310, the mount opening 308 configured to receive a fastener extending through the mount opening 308 and the frame opening 112 at the rack 100.

9. The system 10 of any one or more clauses herein, the bracket 300 including a mount tab 310 extending orthogonal to an extension of the bracket 300 wall, wherein a mount opening 308 extends through the mount tab 310 to form an open-ended opening along the vertical direction.

10. The system 10 of any one or more clauses herein, including a plurality of brackets 300 positioned in adjacent arrangement along the vertical direction.

11. The system 10 of any one or more clauses herein, wherein the chassis 200 is a unitary, monolithic component.

12. The system 10 of any one or more clauses herein, wherein the chassis 200 is a single body of a plastic material.

13. The system 10 of any one or more clauses herein, wherein the chassis 200 is a unitary, monolithic body including polybutylene terephthalate.

14. The system 10 of any one or more clauses herein, wherein the chassis 200 is a unitary, monolithic body including polybutylene terephthalate plus approximately 30% glass fill.

15. The system 10 of any one or more clauses herein, wherein the latch 400 includes a platform 406 extending substantially co-directional to the sidewall 208.

16. The system 10 of any one or more clauses herein, wherein the lock tab 402 extends from the platform 406 at a first end to the user interface tab 404 at a second end distal to the first end.

17. The system 10 of any one or more clauses herein, wherein the lock tab 402 is positioned along the platform 406 between a first end and a second end distal to the first end.

18. The system 10 of any one or more clauses herein, wherein the latch 400 is positioned between the sidewall 208 and the wall 302 of the bracket 300.

19. The system 10 of any one or more clauses herein, wherein the latch 400 is integral to the chassis 200.

20. The system 10 of any one or more clauses herein, wherein the lock tab 402 extends substantially correspondingly to the opening 306 at the bracket 300.

21. The system 10 of any one or more clauses herein, wherein the positioning member 210 is configured to extend through the guide slot 304 at the bracket 300 to provide a contact surface at which the chassis 200 rides on the bracket 300 at the guide slot 304.

22. A system for telecommunications equipment mounting 10 in accordance with aspects of the present disclosure.

23. A telecommunications chassis 200 in accordance with aspects of the present disclosure.

24. An adjustable bracket 300 and telecommunications rack 100 in accordance with aspects of the present disclosure.

25. A method for mounting telecommunications equipment in accordance with aspects of the present disclosure.

26. A chassis for mounting telecommunications equipment 200 in accordance with aspects of the present disclosure.

This written description uses examples to disclose the invention, including the best mode, and also to enable any person skilled in the art to practice the invention, including making and using any devices or systems and performing any incorporated methods. The patentable scope of the invention is defined by the claims, and may include other examples that occur to those skilled in the art. Such other examples are intended to be within the scope of the claims if they include structural elements that do not differ from the literal language of the claims, or if they include equivalent structural elements with insubstantial differences from the literal languages of the claims.

What is claimed is:

1. A system for telecommunications equipment mounting, the system comprising:
a rack comprising a frame, the frame comprising a frame opening;
a bracket attachable to the frame at the frame opening; and
a chassis forming a body comprising sidewalls separated from one another along a width direction and extending along a transverse direction; and
a latch configured to selectively lock and release the chassis relative to the bracket,
wherein the bracket comprises a wall extending co-directional to the sidewalls, the wall forming a guide slot extending co-directional to the sidewalls, the wall forming an opening,
wherein the latch comprises a lock tab configured to extend into the opening at the bracket, the latch comprising a user interface tab configured to articulate the lock tab in and out of the opening.

2. The system of claim 1, wherein the bracket comprises a plurality of openings positioned in adjacent arrangement co-directional to an extension of the sidewalls.

3. The system of claim 1, wherein the latch is attached to the sidewalls.

4. The system of claim 1, the sidewalls comprising a positioning member extending from the sidewall, wherein the positioning member is configured to extend into the guide slot at the bracket.

5. The system of claim 1, the sidewalls comprising a post extending from the sidewall, wherein a positioning member extends from the post into the guide slot at the bracket.

6. The system of claim 1, the sidewalls forming a recess, wherein a post extends from the recess, and wherein a positioning member extends from the post into the guide slot at the bracket.

7. The system of claim 1, the bracket comprising a mount opening configured to receive a fastener extending through the mount opening and the frame opening at the rack.

8. The system of claim 1, the bracket comprising a mount tab extending orthogonal to an extension of the bracket wall, wherein a mount opening extends through the mount tab, the mount opening configured to receive a fastener extending through the mount opening and the frame opening at the rack.

9. The system of claim 1, the bracket comprising a mount tab extending orthogonal to an extension of the bracket wall, wherein a mount opening extends through the mount tab to form an open-ended opening along the vertical direction.

10. The system of claim 1, comprising a plurality of brackets positioned in adjacent arrangement along the vertical direction.

11. The system of claim 1, wherein the chassis is a unitary, monolithic component.

12. The system of claim 1, wherein the chassis is a single body of a plastic material.

13. The system of claim 1, wherein the chassis is a unitary, monolithic body comprising polybutylene terephthalate.

14. The system of claim 1, wherein the chassis is a unitary, monolithic body comprising polybutylene terephthalate plus approximately 30% glass fill.

15. The system of claim 1, wherein the latch comprises a platform extending substantially co-directional to the sidewall.

16. The system of claim 15, wherein the lock tab extends from the platform at a first end to the user interface tab at a second end distal to the first end.

17. The system of claim 15, wherein the lock tab is positioned along the platform between a first end and a second end distal to the first end.

18. The system of claim 1, wherein the latch is positioned between the sidewall and the wall of the bracket, and wherein the latch is integral to the chassis.

19. The system of claim 1, wherein the lock tab extends substantially correspondingly to the opening at the bracket.

20. The system of claim 1, wherein the positioning member is configured to extend through the guide slot at the bracket to provide a contact surface at which the chassis rides on the bracket at the guide slot.
